(19) United States
(12) Patent Application Publication
(10) Pub. No.: US 2024/0290920 A1
(43) Pub. Date: Aug. 29, 2024

(54) DISPLAY APPARATUS

(71) Applicant: Japan Display Inc., Tokyo (JP)

(72) Inventors: Koichi MIYASAKA, Tokyo (JP); Yoshikatsu IMAZEKI, Tokyo (JP); Yoichi KAMIJO, Tokyo (JP); Shuichi OSAWA, Tokyo (JP); Yoshifumi KAMEI, Tokyo (JP)

(21) Appl. No.: 18/587,040

(22) Filed: Feb. 26, 2024

(30) Foreign Application Priority Data
Feb. 28, 2023 (JP) 2023-030287

(51) Int. Cl. H01L 33/58; H01L 25/075

(52) U.S. Cl. CPC H01L 33/58; H01L 25/0753

(57) ABSTRACT

A display apparatus includes a plurality of light-emitting elements arrayed on a substrate, a cover member having a first main surface serving as a display surface and a second main surface opposite to the first main surface, the second main surface being disposed facing the substrate, the cover member having a through hole passing through the first main surface and the second main surface in a region overlapping the light-emitting elements, a protective film covering the light-emitting elements and provided between the substrate and the cover member, and a light-shielding layer provided to at least one of the first main surface and the second main surface of the cover member.

### CROSS-REFERENCE TO RELATED APPLICATION

This application claims the benefit of priority from Japanese Patent Application No. 2023-030287 filed on Feb. 28, 2023, the entire contents of which are incorporated herein by reference.

### BACKGROUND

### 1. Technical Field

The present disclosure relates to a display apparatus.

### 2. Description of the Related Art

Display apparatuses with micro-sized light-emitting diodes (micro LEDs) are provided with optical members, such as polarizing plates, to improve display characteristics. Japanese Patent Application Laid-open Publication No. 2021-129080 (JP-A-2021-129080), for example, describes a display apparatus with a reflection suppression layer disposed on the light-emitting elements. The reflection suppression layer changes the light transmittance by chemical reaction and has light-transmissive openings at the positions directly facing the respective light-emitting elements.

Such display apparatuses are required to improve the efficiency of light extraction to the display surface side while suppressing reflection of unnecessary light other than the light from the light-emitting elements.

### SUMMARY

A display apparatus according to an embodiment of the present disclosure includes a plurality of light-emitting elements arrayed on a substrate, a cover member having a first main surface serving as a display surface and a second main surface opposite to the first main surface, the second main surface being disposed facing the substrate, the cover member having a through hole passing through the first main surface and the second main surface in a region overlapping the light-emitting elements, a protective film covering the light-emitting elements and provided between the substrate and the cover member, and a light-shielding layer provided to at least one of the first main surface and the second main surface of the cover member.

### BRIEF DESCRIPTION OF THE DRAWINGS

FIG. 1 is a plan view schematically illustrating a display apparatus according to an embodiment;

FIG. 2 is a plan view of a pixel of the display apparatus according to the embodiment;

FIG. 3 is a plan view schematically illustrating the arrangement relation between a plurality of light-emitting elements, a cover member, and a light-shielding layer;

FIG. 4 is a sectional view along line IV-IV′ of FIG. 3;

FIG. 5 is a sectional view schematically illustrating the display apparatus according to a first modification;

FIG. 6 is a sectional view schematically illustrating the display apparatus according to a second modification;

FIG. 7 is a sectional view schematically illustrating the display apparatus according to a third modification; and

FIG. 8 is a sectional view schematically illustrating the display apparatus according to a fourth modification.

### DETAILED DESCRIPTION

Exemplary aspects (embodiments) to embody the present disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may illustrate the width, the thickness, the shape, and other elements of each unit more schematically than an actual aspect. These elements, however, are given by way of example only and are not intended to limit interpretation of the present disclosure. In the present disclosure and the drawings, components similar to those previously described with reference to previous drawings are denoted by like reference numerals, and detailed explanation thereof may be appropriately omitted.

To describe an aspect where a first structure is disposed on a second structure in the present specification and the claims, the term “on” includes both of the following cases unless otherwise noted: a case where the first structure is disposed directly on the second structure in contact with the second structure, and a case where the first structure is disposed on the second structure with another structure interposed therebetween.

### Embodiments

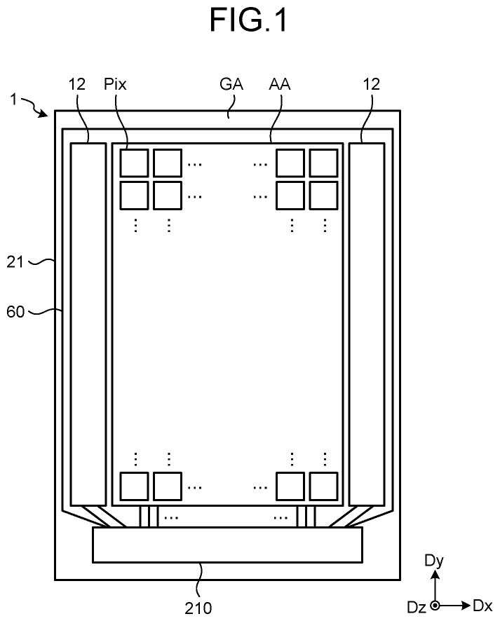

FIG. 1 is a plan view schematically illustrating a display apparatus according to an embodiment. As illustrated in FIG. 1, a display apparatus 1 includes a substrate 21, a plurality of pixels Pix, a scanning circuit 12, a drive integrated circuit (IC) 210, and cathode wiring 60. The substrate 21 is a drive circuit substrate for driving the pixels Pix and is also called a backplane or an active matrix substrate.

As illustrated in FIG. 1, the display apparatus 1 has a display region AA and a peripheral region GA. The display region AA is a region that overlaps the pixels Pix and displays an image. The peripheral region GA is a region not overlapping the pixels Pix and is disposed outside the display region AA.

The pixels Pix are arrayed in a first direction Dx and a second direction Dy in the display region AA of the substrate 21. The first direction Dx and the second direction Dy are parallel to the surface of the substrate 21. The first direction Dx is orthogonal to the second direction Dy. The first direction Dx may intersect the second direction Dy without being orthogonal thereto. A third direction Dz is orthogonal to the first direction Dx and the second direction Dy. The third direction Dz corresponds to the normal direction of the substrate 21, for example. In the following description, plan view refers to the positional relation when viewed from the third direction Dz.

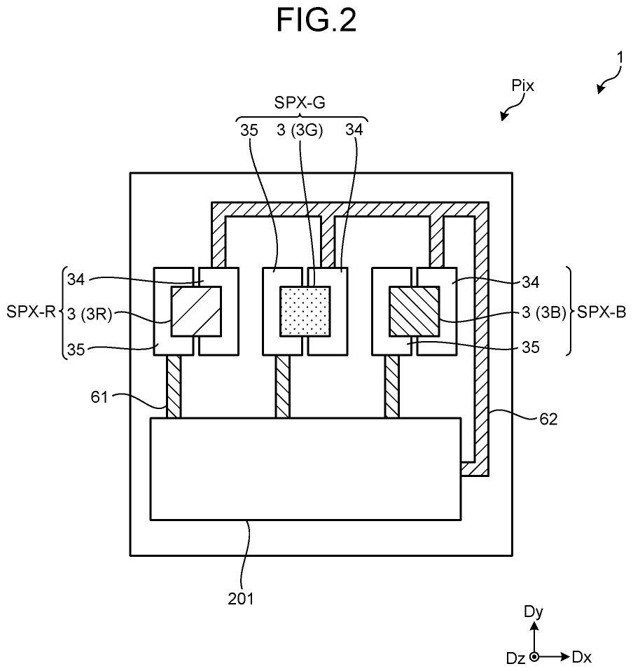

The scanning circuit 12 is a circuit that sequentially selects, row by row, drive circuits 201 (refer to FIG. 2) included in the respective pixels Pix based on various control signals supplied via wiring extending from the drive IC 210. The scanning circuit 12 sequentially or simultaneously selects the drive circuits 201 in each row and supplies control signals to the selected drive circuits 201. As a result, the drive circuits 201 drive light-emitting elements 3 of the pixels Pix.

The drive IC 210 is a circuit that controls display on the display apparatus 1. A plurality of wires (not illustrated) extend from the drive IC 210 toward the drive circuits 201 included in the pixels Pix. The drive IC 210 supplies control signals (pixel signals) to the drive circuits 201 of the respective pixels Pix selected by the scanning circuit 12. The drive circuit 201 supplies drive signals (current) to each light-emitting element 3 due to the control signals from the drive IC 210 and causes the light-emitting element 3 to emit light. The drive IC 210 is mounted in the peripheral region GA of the substrate 21. The present embodiment is not limited thereto, and the drive IC 210 may be mounted on a flexible printed circuit board or a rigid board coupled to the peripheral region GA of the substrate 21.

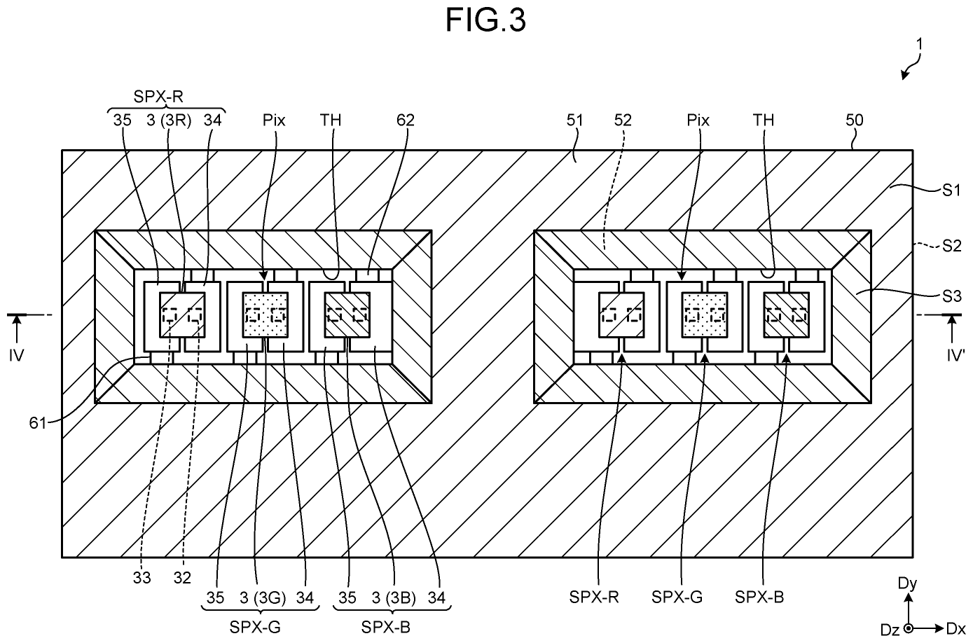

The cathode wiring 60 is provided to the peripheral region GA of the substrate 21. The cathode wiring 60 is provided surrounding the pixels Pix in the display region AA and the scanning circuit 12 in the peripheral region GA. The cathodes of the light-emitting elements 3 are electrically coupled to the common cathode wiring 60 and are supplied with a fixed potential (e.g., a ground potential). More specifically, a cathode terminal 32 (refer to FIG. 3) of the light-emitting element 3 is coupled to the cathode wiring 60 via a cathode electrode 34.

FIG. 2 is a plan view of the pixel of the display apparatus according to the embodiment. As illustrated in FIG. 2, one pixel Pix includes a plurality of pixels SPX and the drive circuit 201. The pixel Pix includes a pixel SPX-R, a pixel SPX-G, and a pixel SPX-B, for example. The pixel SPX-R displays a primary color of red as the first color. The pixel SPX-G displays a primary color of green as the second color. The pixel SPX-B displays a primary color of blue as the third color. As illustrated in FIG. 2, in one pixel Pix, the pixel SPX-R, the pixel SPX-G, and the pixel SPX-B are adjacently disposed in the first direction Dx. The first color, the second color, and the third color are not limited to red, green, and blue, respectively, and may be any desired colors, such as complementary colors. In the following description, the pixel SPX-R, the pixel SPX-G, and the pixel SPX-B are referred to as the pixels SPX when they need not be distinguished from one another.

The pixels SPX each include the light-emitting element 3, a cathode electrode 34, and an anode electrode 35. The display apparatus 1 displays an image by causing a light-emitting element 3R, a light-emitting element 3G, and a light-emitting element 3B in the pixel SPX-R, the pixel SPX-G, and the pixel SPX-B, respectively, to output different light. The light-emitting element 3 is an inorganic light-emitting diode (LED) chip having a size of approximately 3μ m to 300μ m in plan view and is called a micro LED. The display apparatus 1 including the micro LEDs in the respective pixels is also called a micro LED display apparatus. The term “micro” of the micro LED is not intended to limit the size of the light-emitting element 3.

The light-emitting elements 3 may output light in four or more different colors. The arrangement of the pixels SPX is not limited to the configuration illustrated in FIG. 2. One of the pixels SPX, for example, may be disposed side by side with another pixel SPX in the second direction Dy. Alternatively, the pixels SPX may be disposed in a triangular lattice.

The drive circuit 201 is composed of a micro IC, for example, and is provided to each pixel Pix. In the example illustrated in FIG. 2, one drive circuit 201 is provided for three pixels SPX. The drive circuit 201 is coupled to the anode electrode 35 (anode of the light-emitting element 3) of each pixel SPX via wiring 61. The drive circuit 201 is coupled to the cathode electrode 34 (cathode of the light-emitting element 3) of each pixel SPX via wiring 62. The drive circuit 201 performs control such that a predetermined current flows through each light-emitting element 3 based on the scanning signals from the scanning circuit 12 and the control signals (pixel signals) from the drive IC 210 as described above, thereby causing the light-emitting element 3 to emit light.

While FIG. 2 illustrates a configuration where one drive circuit 201 is coupled to three light-emitting elements 3, the embodiment is not limited thereto. Alternatively, one drive circuit 201 may be coupled to one light-emitting element 3 or four or more light-emitting elements 3.

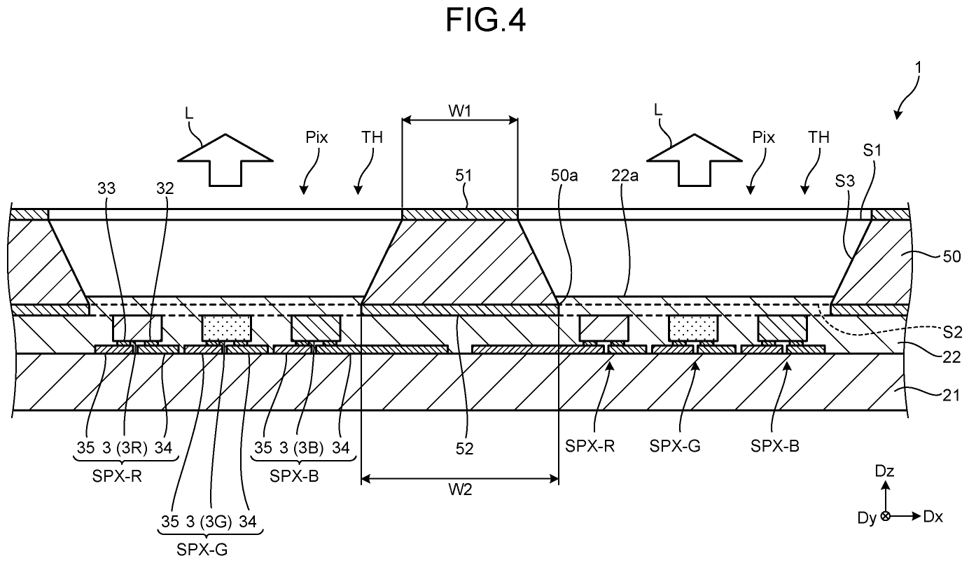

Next, the configuration of the display apparatus 1 is described in detail. FIG. 3 is a plan view schematically illustrating the arrangement relation between a plurality of light-emitting elements, a cover member, and a light-shielding layer. FIG. 4 is a sectional view along line IV-IV′of FIG. 3. In FIG. 3, a light-shielding layer 51 provided on a first main surface S1 of a cover member 50 and a light-shielding layer 52 provided on a second main surface S2 are indicated by different hatching to make the drawing easier to understand.

In the present specification, a direction from the substrate 21 toward the cover member 50 in a direction perpendicular to the surface of the substrate 21 is referred to as an “upper side” or simply as “top”. A direction from the cover member 50 toward the substrate 21 is referred to as a “lower side” or simply as “bottom”.

As illustrated in FIGS. 3 and 4, the light-emitting elements 3 are arrayed on the substrate 21. The substrate 21 is an insulating substrate, such as a glass substrate and a resin substrate. The cathode electrodes 34, the anode electrodes 35, and various kinds of wiring, such as the wiring 61 and 62, are provided on the substrate 21. The cathode electrode 34 and the anode electrode 35 are provided on the same surface of the substrate 21 and are spaced apart from each other. The cathode electrode 34 and the anode electrode 35 are provided for each pixel SPX (light-emitting element 3).

A cathode terminal 32 and an anode terminal 33 of the light-emitting element 3 are provided on the same surface of the light-emitting element 3, facing the upper surface of the substrate 21. The cathode terminal 32 of the light-emitting element 3 is electrically coupled to the cathode electrode 34. The anode terminal 33 of the light-emitting element 3 is electrically coupled to the anode electrode 35.

While the light-emitting elements 3 may have any desired configuration, they can be each composed of an n-type semiconductor layer, an active layer, and a p-type semiconductor layer stacked in this order. The semiconductor layer is made of compound semiconductor, such as gallium nitride (GaN), aluminum indium phosphorous (AlInP), and indium gallium nitride (InGaN). The semiconductor layer may be made of different materials for the respective light-emitting elements 3R, 3G, and 3B. The active layer may have a multi-quantum well structure (MQW structure) in which well layers and barrier layers composed of several atomic layers are cyclically stacked for higher efficiency.

As illustrated in FIG. 4, the display apparatus 1 includes a protective film 22 and a cover member 50. The protective film 22 is provided on the substrate 21 to cover the light-emitting elements 3 and is provided between the substrate 21 and the cover member 50. The protective film 22 also covers the cathode electrodes 34, the anode electrodes 35, and various kinds of wiring, such as the wiring 61 and 62. The protective film 22 is an organic insulating film and is made of organic material, such as photosensitive acrylic. The organic material, such as photosensitive acrylic, is excellent in coverability for level difference caused by the light-emitting elements 3 and various kinds of wiring and surface flatness compared with inorganic insulating material formed by CVD, for example.

The cover member 50 has a plate-like shape similarly to the substrate 21 and is disposed facing the substrate 21. More specifically, the cover member 50 has a first main surface S1 serving as the display surface and a second main surface S2 opposite to the first main surface S1. The second main surface S2 of the cover member 50 is disposed facing the substrate 21 with the protective film 22 interposed therebetween. The cover member 50 is formed using a translucent glass or resin substrate as a base, for example.

A through hole TH passing through the first main surface S1 and the second main surface S2 is formed in the region of the cover member 50 overlapping the light-emitting elements 3. An inner peripheral surface S3 of the through hole TH is inclined and tapered. In other words, the opening width of the through hole TH on the second main surface S2 side is smaller than that on the first main surface S1 side.

Light L from the light-emitting elements 3 passes through the through hole TH and is output toward an observer. In other words, neither glass or the like constituting the cover member 50 nor an optical functional layer (e.g., a polarizing plate) to suppress reflection of light on the wiring 61 and 62 is provided on the light-emitting elements 3. Therefore, the display apparatus 1 according to the present embodiment can improve the extraction efficiency of the light L compared with a configuration where no through hole TH is formed in the cover member 50 and the cover member 50 and the optical function layer are provided covering the light-emitting elements 3.

As illustrated in FIGS. 3 and 4, a plurality of through holes TH are formed for the respective pixels Pix. In other words, the light-emitting elements 3 include the light-emitting element 3R (first light-emitting element), the light-emitting element 3G (second light-emitting element), and the third light-emitting element 3B (third light-emitting element) that output light in different colors, and one through hole TH is formed in the region overlapping the three light-emitting elements 3R, 3G and 3B. Alternatively, as illustrated in FIG. 3, the three pixels SPX-R, SPX-G, and SPX-B (light-emitting elements 3R, 3G, and 3B) are disposed in the region surrounded by the inner peripheral surface S3 of the through hole TH in plan view.

This configuration facilitates alignment of the cover member 50 with the light-emitting elements 3 compared with a case where the through holes TH are formed for the respective pixels SPX. In other words, this configuration can suppress reduction in extraction efficiency of the light L if the cover member 50 is misaligned with respect to the light-emitting elements 3. This configuration also facilitates processing the through holes TH of the cover member 50 compared with a case where the through holes TH are formed for the respective pixels SPX. Therefore, the through holes TH can be formed with high accuracy if the cover member 50 is thick.

As illustrated in FIGS. 3 and 4, the light-shielding layer 51 is provided on the first main surface S1 of the cover member 50. The light-shielding layer 52 is provided on the second main surface S2 of the cover member 50. More specifically, the light-shielding layer 51 is continuously formed covering the first main surface S1 of the cover member 50, except for the opening portion of the through hole TH on the first main surface S1 side. Similarly, the light-shielding layer 52 is continuously formed covering the second main surface S2 of the cover member 50, except for the opening portion of the through hole TH on the second main surface S2 side.

As described above, the through hole TH is tapered, and the width W2 of the light-shielding layer 52 on the second main surface S2 is larger than the width W1 of the light-shielding layer 51 on the first main surface S1 between adjacent through holes TH (that is, between adjacent pixels Pix). In the present embodiment, no light-shielding layer is provided on the inner peripheral surface S3 of the through hole TH. As illustrated in FIG. 3, part of the light-shielding layer 52 on the second main surface S2 is disposed in a frame shape in the region overlapping the inner peripheral surface S3 in plan view.

The light-shielding layers 51 and 52 are made of material having higher light absorbance than the glass or resin substrate constituting the cover member 50. The light-shielding layers 51 and 52 are black members and are made of resin material colored in black, for example. The light-shielding layer 51 is applied and formed on the first main surface S1, and the light-shielding layer 52 is applied and formed on the second main surface S2. The present embodiment is not limited thereto, and the light-shielding layers 51 and 52 may be made of carbon or other materials, such as metal oxides, carbides, and metal carbides, that appear in black due to thin-film interference.

Thus, the light-shielding layers 51 and 52 are not provided in the region overlapping the light-emitting elements 3, but are provided in the region overlapping various kinds of wiring such as the wiring 61 and 62 and the drive circuit 201 (refer to FIG. 2). With this configuration, external light is blocked by the light-shielding layers 51 and 52, and unnecessary light reflected on various kinds of wiring, such as the wiring 61 and 62, can be reduced. Therefore, the display apparatus 1 can improve the display characteristics.

The light-shielding layer 51 is provided on the first main surface S1 of the cover member 50, and the light-shielding layer 52 is provided on the second main surface S2 of the cover member 50. With this configuration, unnecessary light reflected on various kinds of wiring, such as the wiring 61 and 62, can be effectively reduced. The light-shielding layer 52 is provided on the second main surface S2 closer to the light-emitting elements 3. With this configuration, the light-shielding layer 52 can block the light L traveling in an oblique direction from the light-emitting elements 3 toward the adjacent pixels Pix, thereby suppressing color mixture of the light L between the pixels Pix.

The present embodiment is not limited thereto, and the light-shielding layers 51 and 52 simply need to be provided on at least one of the first main surface S1 and the second main surface S2 of the cover member 50. The light-shielding layers 51 and 52 are provided on the first main surface S1 and the second main surface S2 of the cover member 50, and the cover member 50 also serves as a reflection suppression layer to suppress reflection of light. Therefore, the number of layers in the display apparatus 1 can be reduced compared with a case where the light-shielding layers 51 and 52 are provided as separate optical members between the cover member 50 and the substrate 21.

The protective film 22 according to the present embodiment protects the light-emitting elements 3 and also serves as an adhesive layer between the substrate 21 and the cover member 50. As illustrated in FIG. 4, the second main surface S2 of the cover member 50 (more precisely, the light-shielding layer 52 provided on the second main surface S2) is in direct contact with the protective film 22 and faces the substrate 21. Part of the cover member 50 on the second main surface S2 side is embedded in the protective film 22, and an opening end 50a of the inner peripheral surface S3 of the through hole TH on the second main surface S2 side is covered by the protective film 22.

The through hole TH also functions as a ventilation hole to release air between the cover member 50 and the protective film 22 to the outside. In other words, the through holes TH is formed in the cover member 50, and thereby air between the cover member 50 and the protective film 22 can be released through the through holes TH to the outside in the process of bonding the cover member 50 and the substrate 21 together. Therefore, the display apparatus 1 can prevent air bubbles from being generated between the cover member 50 and the protective film 22, whereby the cover member 50 and the substrate 21 can be satisfactorily bonded together.

With the protective film 22 also serving as an adhesive layer for the cover member 50, the distance between the cover member 50 (light-shielding layers 51 and 52) and the light-emitting elements 3 in the third direction Dz can be reduced. Therefore, the light-shielding layers 51 and 52 also function as partition walls between the pixels Pix and can satisfactorily suppress color mixture between the pixels Pix.

FIGS. 3 and 4 only schematically illustrate the display apparatus 1 to facilitate understanding. For example, the inclination angle of the inner peripheral surface S3 of the through hole TH is illustrated in an emphasized manner and may actually be nearly vertical. While the through hole TH has a rectangular shape in plan view, the present embodiment is not limited thereto. The through hole TH may have other shapes, such as circular, elliptical, and oval shapes.

While the pixel Pix includes a micro IC as the drive circuit 201 in the description above, the present embodiment is not limited thereto. Instead of the drive circuit 201, a pixel circuit including a plurality of thin-film transistors may be provided for each pixel SPX, for example.

### First Modification

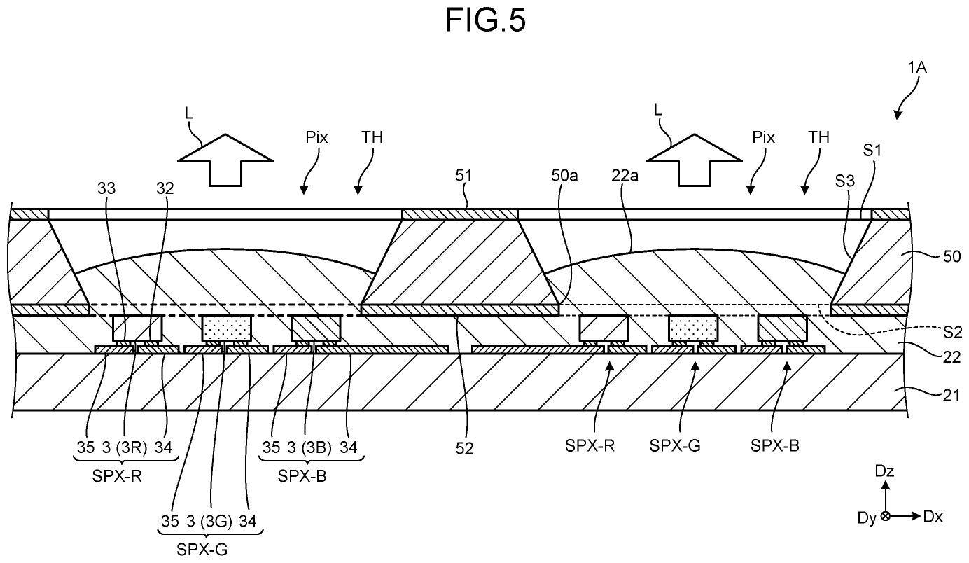

FIG. 5 is a sectional view schematically illustrating the display apparatus according to a first modification. As illustrated in FIG. 5, in a display apparatus 1A according to the first modification, part of the protective film 22 is disposed in the through hole TH of the cover member 50. In the region where the through hole TH is formed, a surface 22a of the protective film 22 has a curved surface protruding in a direction from the substrate 21 toward the first main surface S1. The protruding protective film 22 is formed such that part of the protective film 22 is pushed into the through hole TH and rises due to surface tension when the cover member 50 and the substrate 21 are bonded together.

The protective film 22 in the through hole TH has effects of a convex lens. As a result, the light L output from the light-emitting elements 3 passes through the protruding protective film 22 and is condensed in the third direction Dz, and the light L output from the light-emitting elements 3 in an oblique direction is also directed in the third direction Dz. Therefore, the display apparatus 1A can improve the luminance on the display surface side (third direction Dz).

### Second Modification

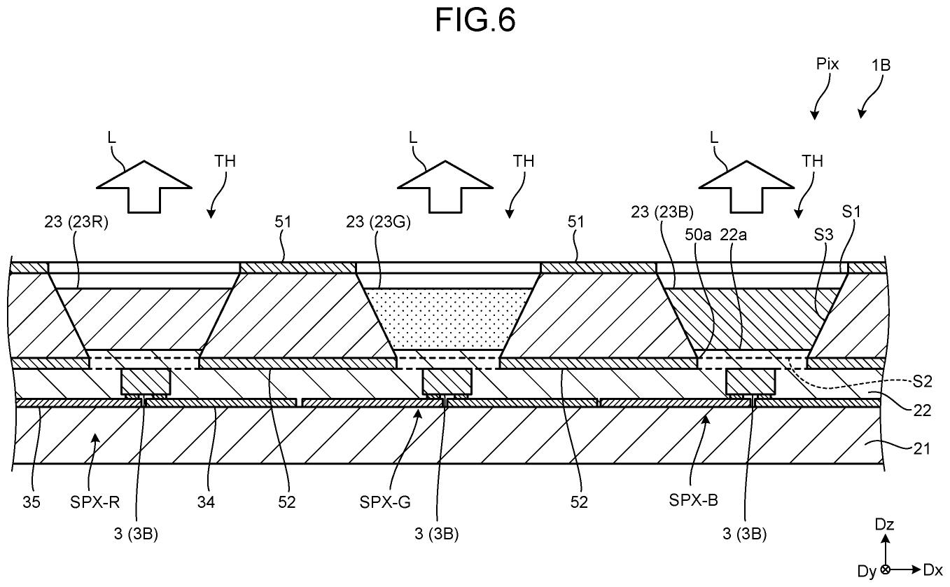

FIG. 6 is a sectional view schematically illustrating the display apparatus according to a second modification. As illustrated in FIG. 6, a display apparatus 1B according to the second modification includes a color conversion layer 23 that converts the wavelength of the light L output from the light-emitting element 3. More specifically, the through holes TH are formed for the respective pixels SPX-R, SPX-G, and SPX-B. In other words, the through holes TH are provided in the regions overlapping the respective light-emitting elements 3. Each pixel SPX according to the present embodiment includes the light-emitting element 3 (e.g., light-emitting element 3B) that outputs the light L in the same color.

A color conversion layer 23R is provided inside the through holes TH corresponding to the pixels SPX-R, a color conversion layer 23G is provided inside the through holes TH corresponding to the pixels SPX-G, and a color conversion layer 23B is provided inside the through holes TH corresponding to the pixels SPX-B. The color conversion layers 23R, 23G, and 23B may be made of phosphor, for example. The color conversion layer 23R absorbs the light L output from the light-emitting element 3B in the pixel SPX-R and outputs wavelength-converted red light. The color conversion layer 23G absorbs the light L output from the light-emitting element 3B in the pixel SPX-G and outputs wavelength-converted green light. The color conversion layer 23B absorbs the light L output from the light-emitting element 3B in the pixel SPX-B and outputs wavelength-converted blue light.

In the second modification, the color conversion layers 23R, 23G, and 23B can be provided using the through holes TH of the cover member 50. Therefore, it is unnecessary to perform patterning of the color conversion layers 23R, 23G, and 23B, and the color conversion layers 23R, 23G, and 23B can be disposed for each of the pixels SPX in a simpler manner. The color conversion layers 23R, 23G, and 23B are provided in the through holes TH. Therefore, the number of layers in the display apparatus 1B can be reduced compared with a case where the color conversion layers 23R, 23G, and 23B are provided in a layer separated from the cover member 50.

The color conversion layer 23 provided in the through hole TH is not necessarily made of phosphor and may be other optical functional layers, such as a color filter. Instead of the color conversion layer 23, other optical functional layers may be provided inside the through hole TH.

### Third Modification

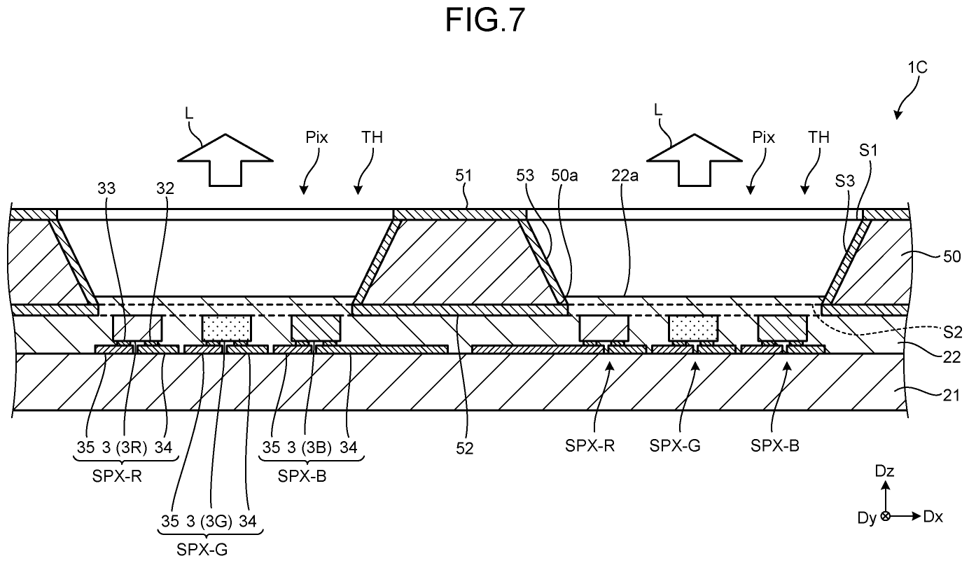

FIG. 7 is a sectional view schematically illustrating the display apparatus according to a third modification. The embodiment and the modifications described above have the configuration where the light-shielding layer 51 is provided on the first main surface S1 of the cover member 50 and the light-shielding layer 52 is provided on the second main surface S2 of the cover member 50. However, the present disclosure is not limited thereto. As illustrated in FIG. 7, a display apparatus 1C according to the third modification further includes a light-shielding layer 53 provided on the inner peripheral surface S3 of the through hole TH. The light-shielding layer 53 is the same black member as the light-shielding layers 51 and 52 and is made of resin material colored in black, for example. The light-shielding layer 53 on the inner peripheral surface S3 is provided surrounding the light-emitting elements 3 included in the pixel Pix in plan view, which is not illustrated in the figure.

With this configuration, the display apparatus 1C according to the third modification can more effectively block external light and reduce unnecessary light reflected on various kinds of wiring, such as the wiring 61 and 62. The light-shielding layer 53 can also block the light L traveling in an oblique direction from the light-emitting elements 3, thereby suppressing color mixture between the pixels Pix.

### Fourth Modification

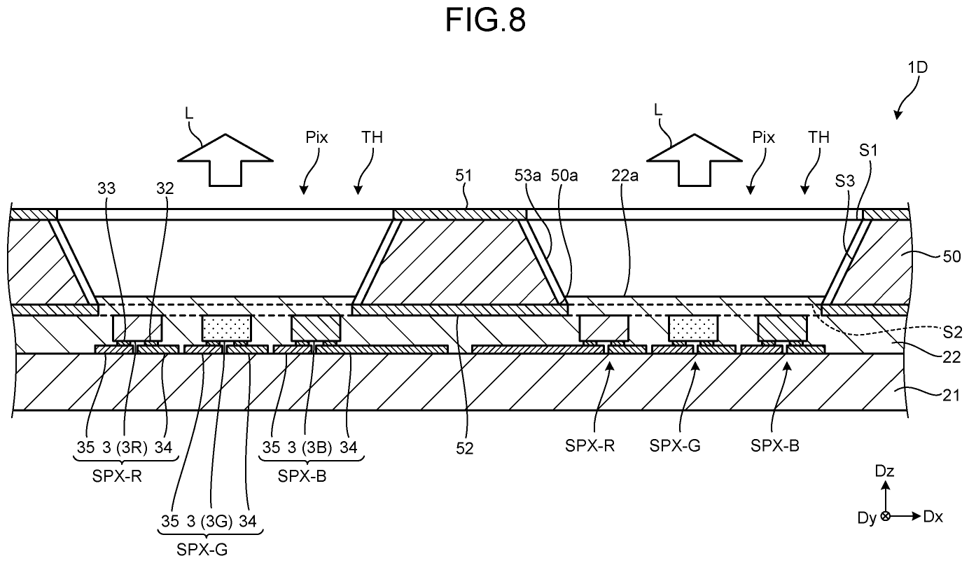

FIG. 8 is a sectional view schematically illustrating the display apparatus according to a fourth modification. As illustrated in FIG. 8, a display apparatus 1D according to the fourth modification includes a light-shielding layer 53a provided on the inner peripheral surface S3 of the through hole TH. The light-shielding layer 53a is a white member different from the light-shielding layers 51 and 52 and is made of resin material colored in white, for example. The light-shielding layers 51 and 52 provided on the first main surface S1 and the second main surface S2 are black members as in the examples described above.

In the fourth modification, the white light-shielding layer 53a is provided around the outer periphery of the pixel Pix, and part of the light-shielding layer 52 is disposed in the region overlapping the light-shielding layer 53a. With this configuration, the apparent aperture ratio of the pixel Pix can be increased while suppressing unnecessary reflection of external light. The white light-shielding layer 53a can also reflect the light L traveling in an oblique direction from the light-emitting elements 3 toward the display surface. In this case, the front luminance can be improved. To increase the front luminance, the light-shielding layer 53a formed on the inner peripheral surface S3 may be a metal film made of aluminum or silver, for example.

While exemplary embodiments according to the present disclosure have been described, the embodiments are not intended to limit the present disclosure. The contents disclosed in the embodiments are given by way of example only, and various modifications may be made without departing from the spirit of the present disclosure. Appropriate modifications made without departing from the spirit of the present disclosure naturally fall within the technical scope of the present disclosure. At least one of various omissions, substitutions, and modifications of the components may be made without departing from the gist of the embodiments above and the modifications thereof.

What is claimed is:

1. A display apparatus comprising:
a plurality of light-emitting elements arrayed on a substrate;
a cover member having a first main surface serving as a display surface and a second main surface opposite to the first main surface, the second main surface being disposed facing the substrate, the cover member having a through hole passing through the first main surface and the second main surface in a region overlapping the light-emitting elements;
a protective film covering the light-emitting elements and provided between the substrate and the cover member; and
a light-shielding layer provided to at least one of the first main surface and the second main surface of the cover member.

2. The display apparatus according to claim 1, wherein
the cover member has a plurality of the through holes,
the light-shielding layer is provided to both the first main surface and the second main surface, and
the width of the light-shielding layer on the second main surface is larger than the width of the light-shielding layer on the first main surface between the through holes adjacent to each other.

3. The display apparatus according to claim 2, wherein
an inner peripheral surface of the through hole is inclined, and
the opening width of the through hole on the second main surface side is smaller than the opening width of the through hole on the first main surface side.

4. The display apparatus according to claim 3, wherein the light-shielding layer is further provided to the inner peripheral surface of the through hole.

5. The display apparatus according to claim 4, wherein the light-shielding layer is a black member.

6. The display apparatus according to claim 4, wherein
the light-shielding layer provided to at least one of the first main surface and the second main surface is a black member, and
the light-shielding layer provided to the inner peripheral surface of the through hole is a white member or a metal film.

7. The display apparatus according to claim 1, wherein the protective film is in direct contact with the light-shielding layer provided to the second main surface of the cover member.

8. The display apparatus according to claim 1, wherein a surface of the protective film has a curved surface protruding in a direction from the substrate toward the first main surface in a region where the through hole is formed.

9. The display apparatus according to claim 1, wherein
the light-emitting elements include a first light-emitting element, a second light-emitting element, and a third light-emitting element configured to output light in different colors, and
one through-hole is provided in a region overlapping the first light-emitting element, the second light-emitting element, and the third light-emitting element.

10. The display apparatus according to claim 1, wherein
the through holes are provided in regions overlapping the respective light-emitting elements, and
the display apparatus comprises a color conversion layer provided inside each of the through holes and configured to convert a wavelength of light output from the light-emitting element.

11. The display apparatus according to claim 1, wherein the cover member is a glass plate.
